(19) United States
(12) Patent Application Publication
(10) Pub. No.: US 2011/0005728 A1
(43) Pub. Date: Jan. 13, 2011

(54) HEAT DISSIPATION MODULE

(75) Inventors: BO HONG, Shenzhen City (CN); YONG ZHANG, Shenzhen City (CN); WEI-HSIANG CHANG, Tu-Cheng (TW)

Correspondence Address: Altis Law Group, Inc.;ATTN: Steven Reiss, 288 SOUTH MAYO AVENUE, CITY OF INDUSTRY, CA, 91789, US

(73) Assignees: FURUI PRECISE COMPONENT (KUNSHAN) CO., LTD., KunShan City (CN); FOXCONN TECHNOLOGY CO., LTD., Tu-Cheng (TW)

(21) Appl. No.: 12/560,393

(22) Filed: Sep. 15, 2009

(30) Foreign Application Priority Data
Jul. 7, 2009 (CN) 200910304092.1

(51) Int. Cl. F28D 15/04; F28F 7/00; H05K 7/20

(52) U.S. Cl. 165/104.26; 165/122

(57) ABSTRACT

A heat dissipation module comprises a heat pipe forming a condensing section, and a first fin unit and a second fin unit contacting with the condensing section of the heat pipe. The first and second fin units are located neighboring to each other and have different heights. The first and second fin units each comprise a plurality of fins stacked together. A protruding member protrudes from one of the fins of one of the first and second fin units to abut a corresponding neighboring one of the fins of the other one of the first and second fin units, to thereby separate the first fin unit and the second fin unit to limit relative movement of the first fin unit and the second fin unit in a protruding direction of the protruding member.

### BACKGROUND

1. Technical Field

The present disclosure relates to heat dissipation modules, and particularly to a heat dissipation module which can be assembled easily.

2. Description of Related Art

With continuing development of electronic technology, heat-generating electronic components such as CPUs (central processing units) are generating more and more heat which requires immediate dissipation. Generally, heat dissipation modules are attached to the electronic components to provide such dissipation. A conventional heat dissipation module includes a fin unit, a heat pipe and a cooling fan. The heat pipe connects the electronic component with the fin unit to transfer heat from the electronic component to the fin unit. The cooling fan defines an air outlet facing the fin unit to provide forced airflow to cool the fin unit. However, the fin unit generally has a plurality of fins with different sizes for mounting to different portions of the air outlet. Assembly of the heat dissipation module is thus complex and inconvenient.

Therefore, a heat dissipation module is desired to overcome the above described shortcoming.

### BRIEF DESCRIPTION OF THE DRAWINGS

FIG. 1 is an assembled, isometric view of a heat dissipation module in accordance with a first embodiment.

FIG. 2 is a front side view of the heat dissipation module of FIG. 1, with a cooling fan thereof being omitted.

FIG. 3 is an isometric view of a leftmost fin of a first fin unit of the heat dissipation module of FIG. 1.

FIG. 4 is similar to FIG. 2, but shows a heat dissipation module in accordance with a second embodiment.

### DETAILED DESCRIPTION

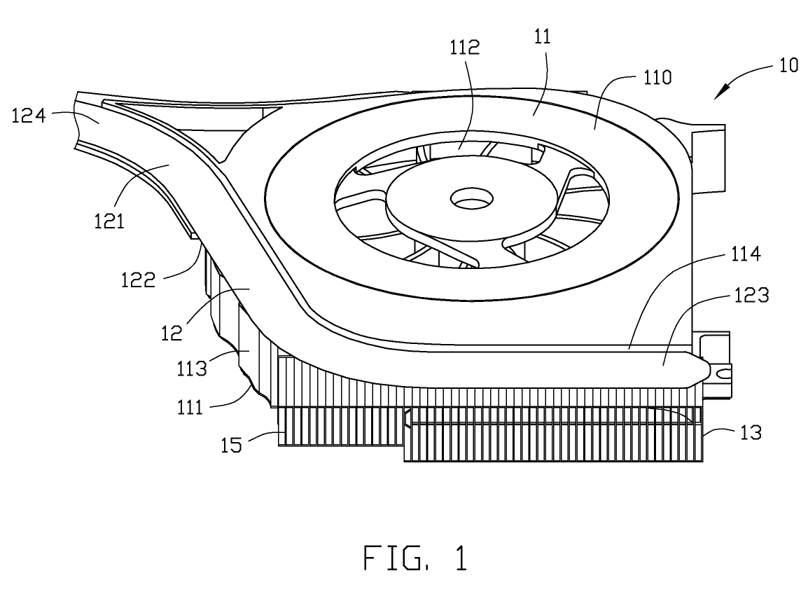

FIG. 1 shows a heat dissipation module 10 in accordance with a first embodiment of the present disclosure. The heat dissipation module 10 includes a cooling fan 11, a heat pipe 12, a first fin unit 13 and a second fin unit 15.

The cooling fan 11 includes a top wall 110, a bottom wall 111 and a sidewall 113 interconnecting the top wall 110 and the bottom wall 111. The cooling fan 11 defines an air inlet 112 at the top wall 110 and an air outlet 114 at the sidewall 113 perpendicular to the air inlet 112. The heat pipe 12 is flat, including a planar top surface 121 and a planar bottom surface 122. The heat pipe 12 includes an evaporating section 124 for absorbing heat from electronic components, and a condensing section 123 located at a top side of the air outlet 114 of the cooling fan 11. The condensing section 123 of the heat pipe 12 is parallel to the air outlet 114 of the cooling fan 11.

The first and second fin units 13, 15 are located at the air outlet 114 of the cooling fan 11 and have top sides thereof connecting with the bottom surface 122 of the condensing section 123 of the heat pipe 12. The first fin unit 13 is located at a right portion of the air outlet 114 of the cooling fan 11 in which the airflow has a relatively high speed. The second fin unit 15 is located at a left portion of the air outlet 114 of the cooling fan 11 in which the airflow has a relatively low speed. The second fin unit 15 is connected to a left side of the first fin unit 13. The second fin unit 15 has a height in an axial direction of the cooling fan 11 smaller than that of the first fin unit 13. The top side of the first fin unit 13 is coplanar with the top side of the second fin unit 15, whilst a bottom side of the first fin unit 13 is lower than a bottom side of the second fin unit 15.

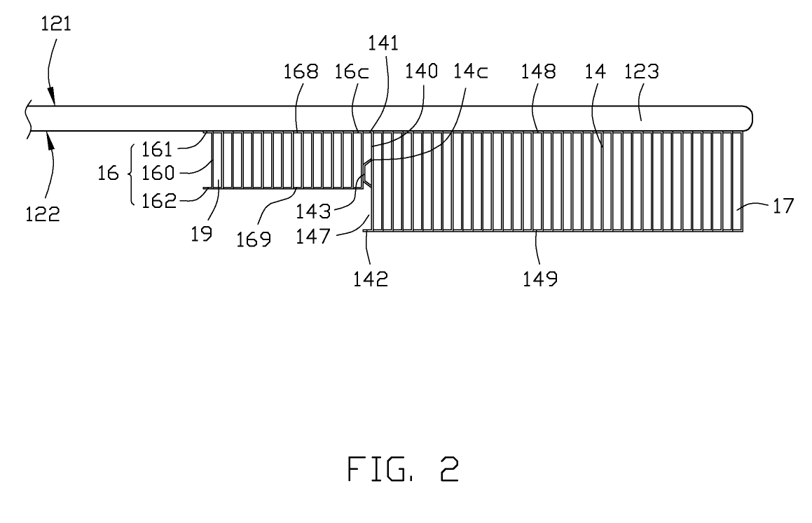

Referring to FIG. 2, the first fin unit 13 comprises a plurality of parallel fins 14 stacked together along the condensing section 123 of the heat pipe 12. Each of the fins 14 includes a main body 140, and top and bottom flanges 141, 142 respectively extending leftward from top and bottom edges of the main body 140. The top and bottom flanges 141, 142 of each fin 14 of the first fin unit 13 are integrally formed with the main body 140. The top and bottom flanges 141, 142 of each fin 14 of the first fin unit 13, except a leftmost fin 14c, abut the main body 140 of a neighboring left fin 14, and thus an air passage 17 is defined between every two neighboring fins 14 of the first fin unit 13. The top flanges 141 of the fins 14 cooperatively form a planar upper surface 148 at the top side of the first fin unit 13. The bottom flanges 142 of the fins 14 cooperatively form a planar lower surface 149 at the bottom side of the first fin unit 13.

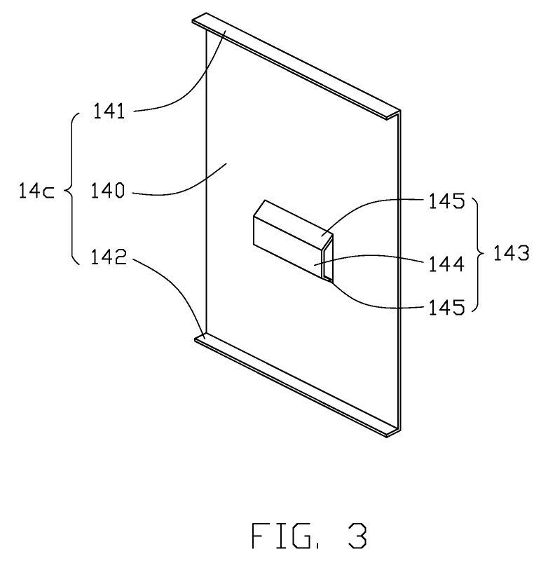

Referring to FIG. 3, the main body 140 of the leftmost fin 14c of the first fin unit 13 forms a protruding member 143 at a central portion thereof by punching. The protruding member 143 protrudes leftward with a length in a protruding direction equaling to a length of each of the top and bottom flanges 141, 142 of the leftmost fin 14c of the first fin unit 13. The protruding member 143 includes a base 144 and a pair of side flanges 145. The base 144 is substantially rectangular and located at a left side of the main body 140 of the leftmost fin 14c of the first fin unit 13. The base 144 is spaced from and parallel to the main body 140 of the leftmost fin 14c. The side flanges 145 connect top and bottom sides of the base 144 with the main body 140 of the leftmost fin 14c of the first fin unit 13.

The second fin unit 15 is similar to the first fin unit 13. The second fin unit 15 includes plural fins 16 stacked together along the condensing section 123 of the heat pipe 12. The fins 16 of the second fin unit 15 each include a main body 160, and top and bottom flanges 161, 162 extending leftward from top and bottom edges of the main body 160. The top and bottom flanges 161, 162 of each fin 16 of the second fin unit 15 abut the main body 160 of a neighboring left fin 16, and thus every two neighboring fins 16 of the second fin unit 15 cooperatively define an air passage 19 therebetween. The top flanges 161 of the fins 16 cooperatively form a planar upper surface 168 at the top side of the second fin unit 15. The bottom flanges 162 of the fins 16 cooperatively form a planar lower surface 169 at the bottom side of the second fin unit 15.

When assembled, the top surface 168 of the second fin unit 15 and the top surface 148 of the first fin unit 13 are connected to the bottom surface 122 of the heat pipe 12 at the condensing section 123. The second fin unit 15 is located at a left side of the first fin unit 13. The lower surface 169 of the second fin unit 15 is higher than the lower surface 149 of the first fin unit 13, and is substantially aligned with a middle portion of the first fin unit 13.

The leftmost fin 14c of the first fin unit 13 is located adjacent to a rightmost fin 16c of the second fin unit 15 with the top flange 141 of the leftmost fin 14c of the first fin unit 13 abutting a top end of the main body 160 of the rightmost fin 16c of the second fin unit 15. The base 144 of the protruding member 143 of the leftmost fin 14c abuts the main body 160 of the rightmost fin 16c of the second fin unit 15, to thereby separate the leftmost fin 14c of the first fin unit 13 and the rightmost fin 16c of the second fin unit 15 with a predetermined distance, and thus a space 147 is formed between the main bodies 140, 160 of the leftmost fin 14c of the first fin unit 13 and the rightmost fin 16c of the second fin unit 15.

During operation, the evaporating section 124 of the heat pipe 12 receives heat from electronic components and transfers the heat to the condensing section 123, and then to the first and second fin units 13, 15 such that air in the air passages 17, 19 is heated. The cooling fan 11 generates forced airflow to blow away the heated air in the air passages 17, 19 of the first and second fin units 13, 15.

Since the protruding member 143 of the leftmost fin 14c of the first fin unit 13 separates the leftmost fin 14c of the first fin unit 13 and the rightmost fin 16c of the second fin unit 15, the rightmost fin 16c of the second fin unit 15 is kept from the first fin unit 13 a constant distance, and thus a total length of the first and second fin units 13, 15 would not decrease. Furthermore, the top flange 161 of the rightmost fin 16c of the second fin unit 15 would not move to a position under the top flange 141 of the leftmost fin 14c of the first fin unit 13, to thereby assure a position of the second fin unit 15 to be always correctly located. Accordingly, assembly of the second fin unit 15 and the heat pipe 12 can be conveniently proceeded, and a good contact of the condensing section 123 of the heat pipe 12 and the top flanges 141 of the second fin unit 15 can be achieved to enhance heat conduction therebetween. Moreover, the space 147 maintained between the main bodies 140, 160 of the leftmost fin 14c of the first fin unit 13 and the rightmost fin 16c of the second fin unit 16c allows the forced airflow flowing therethrough, whereby heat of the leftmost fin 14c and the rightmost fin 16c can be taken away timely.

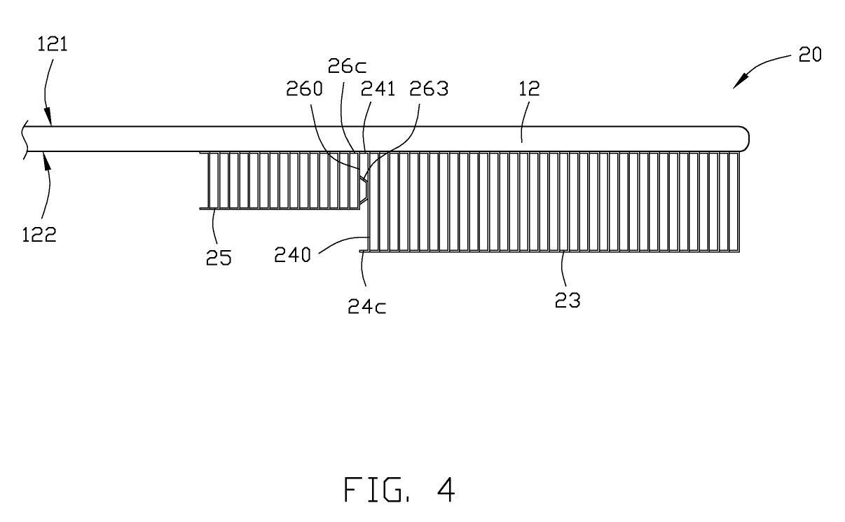

FIG. 4 shows a heat dissipation module 20 in accordance with an alternative embodiment of the present disclosure. The heat dissipation module 20 differs from the heat dissipation module 10 of the previous embodiment only in that a protruding member 263 is formed on a main body 260 of a rightmost fin 26c of a second fin unit 25. The protruding member 263 extends rightward from the main body 260 of the rightmost fin 26c of the second fin unit 25 to abut a main body 240 of the leftmost fin 24c of the first fin unit 23. A shape of the protruding member 263 is similar to that of the protruding member 243 of the heat dissipation module 10 of the previous embodiment. A length of the protruding member 263 in a protruding direction equals to a length of a top flange 241 of the leftmost fin 24c of the first fin unit 23.

It is to be understood, however, that even though numerous characteristics and advantages of the disclosure have been set forth in the foregoing description, together with details of the structure and function of the embodiments, the disclosure is illustrative only, and changes may be made in detail, especially in matters of shape, size, and arrangement of parts within the principles of the invention to the full extent indicated by the broad general meaning of the terms in which the appended claims are expressed.

What is claimed is:

1. A heat dissipation module, comprising:
a heat pipe having a evaporating section adapted for contacting with a heat generating component to absorb heat and a condensing section;
a first fin unit attaching to the condensing section of the heat pipe, the first fin unit comprising a plurality of fins stacked along the condensing section of the heat pipe; and
a second fin unit attaching to the condensing section of the heat pipe, and being located neighboring to the first fin unit, the second fin unit having a height different from that of the first fin unit, the second fin unit comprising a plurality of fins stacked along the condensing section of the heat pipe, a protruding member protruding from one of the fins of one of the first fin unit and the second fin unit to abut a corresponding neighboring one of the fins of the other one of the first fin unit and the second fin unit to separate the first fin unit and the second fin unit to limit relative movement of the first fin unit and the second fin unit in a protruding direction of the protruding member.

2. The heat dissipation module of claim 1, wherein each fin of the first and second fin units comprises a main body and a pair of flanges bending from top and bottom edges of the main body, the flanges at the top edges of the fins of each fin unit forming a planar upper surface, the heat pipe being flat and forming a planar bottom surface contacting with the upper surfaces of the first and second fin units.

3. The heat dissipation module of claim 2, wherein the height of the first fin unit is larger than that of the second fin unit.

4. The heat dissipation module of claim 3, wherein the top and bottom flanges of the fins of the first fin unit and the second fin unit extend toward a same side, and the top flange of the one of the fins forming the protruding member abuts against the main body of the corresponding neighboring one of the fins.

5. The heat dissipation module of claim 4, wherein the protruding member is formed on an outmost fin of the first fin unit, the protruding member protrudes toward a corresponding neighboring fin of the second fin unit with a length in a protruding direction equaling to a length of the top flange of the outmost fin of the first fin unit.

6. The heat dissipation module of claim 4, wherein the protruding member is formed on an outmost fin of the second fin unit, the protruding member protrudes toward a corresponding neighboring fin of the first fin unit with a length in a protruding direction equaling to a length of the top flange of the outmost fin of the second fin unit.

7. The heat dissipation module of claim 4, wherein the protruding member comprises a base spaced from the main body and a pair of side flanges connecting the base with the main body.

8. The heat dissipation module of claim 1, further comprising a cooling fan defining an air outlet facing the first and second fin units.

9. A heat dissipation module, comprising:
a first fin unit comprising a plurality of fins stacked together, each of the fins of the first fin unit comprising a main body and top and bottom flanges respectively extending from top and bottom edges of the main body; and
a second fin unit being located neighboring to the first fin unit, the second fin unit having a height different from that of the first fin unit, the second fin unit comprising a plurality of fins stacked together, each of the fins of the second fin unit comprising a main body and top and bottom flanges respectively extending from top and bottom edges of the main body, the second fin unit comprising an outmost fin neighboring to an outmost fin of the first fin unit, the main body of one of the outmost fins of the first and second fin units forming a protruding member protruding to abut the main body of the other one of the outmost fins of the first and second fin units.

10. The heat dissipation module of claim 9, further comprising a heat pipe forming a planar bottom surface, the top flanges of the first and second fin units contacting the bottom surface of the heat pipe tightly.

11. The heat dissipation module of claim 9, wherein the protruding member comprises a base spaced from the main body and a side flange connecting the base with the main body.
